(19) United States
(12) Patent Application Publication
(10) Pub. No.: US 2012/0247544 A1
(43) Pub. Date: Oct. 4, 2012

(54) SOLAR CELL

(75) Inventors: Young Moon Choi, Seoul (KR); Yun Gi Kim, Yongin-si (KR); Dong Kyun Kim, Suwon-si (KR); Deok-Kee Kim, Yongin-si (KR); Eun Cheol Do, Yongin-si (KR)

(73) Assignee: SAMSUNG ELECTRONICS CO., LTD., Suwon-si (KR)

(21) Appl. No.: 13/296,833

(22) Filed: Nov. 15, 2011

(30) Foreign Application Priority Data
Apr. 1, 2011 (KR) 10-2011-0030280

(51) Int. Cl. H01L 31/06

(52) U.S. Cl. 136/255

(57) ABSTRACT

According to example embodiments, a solar cell includes a plurality of unit portions. Each of the unit portions may have a stacked structure including a plurality of photoelectric members and at least one insulating layer disposed between the photoelectric members. The photoelectric members in different levels may have different energy bandgaps. The photoelectric members in a level may be connected to each other.

### RELATED APPLICATIONS

This application claims priority under 35 U.S.C. §119 to the benefit of Korean Patent Application No. 10-2011-0030280 filed in the Korean Intellectual Property Office on Apr. 1, 2011, the entire contents of which are incorporated herein by reference.

### BACKGROUND

1. Field

Example embodiments relate to a solar cell.

2. Description

The main energy source that is currently used is the fossil fuel such as coal and petroleum. However, the fossil fuel causes problems such as global warming and environmental pollution as well as being gradually exhausted. Solar light, tidal power, wind power, geothermal heat and the like are being studied as an alternative energy source for replacing fossil fuel.

Among them, technology of converting solar light into electricity takes the lead. Various materials and devices are being developed for the efficient conversion of solar light into electricity, and for example, technology based on the multi-layered p-n junction structure and III-V Group materials accomplishes higher light conversion efficiency.

The above-described technology may use specific wavelength of solar light among various wavelengths. A multijunction structure may be applied to use several wavelengths. Techniques for effectively using the currents generated by multijunction solar cells are being studied.

### SUMMARY

According to example embodiments, a solar cell includes a plurality of unit portions. Each of the unit portions may include a stacked structure including a plurality of photoelectric members at a plurality of levels and at least one insulating layer between the photoelectric members. The photoelectric members at different levels may have different energy bandgaps, and the photoelectric members at the same level may be connected to each other.

The photoelectric members at the same levels may be configured to generate currents with the same magnitude. The photoelectric members at different levels may be configured to generate currents with different magnitudes.

The photoelectric members at the same levels may be configured to generate voltages with the same magnitude, and the photoelectric members at different levels may be configured to generate voltages with different magnitudes.

The photoelectric members in each level may form at least one series, and the photoelectric members in each of at least one series may be connected in series.

The series in different levels may be configured to generate substantially the same terminal voltages and the series in different levels may be connected in parallel to each other.

Each of the unit portions may include a double-layered structure. The plurality of photoelectric members in each unit portion may include a first photoelectric member, and a second photoelectric member electrically separated from the first photoelectric member, wherein the first photoelectric member and the second photoelectric member are in different levels.

Each of the unit portions may further include a pair of first terminals connected to the first photoelectric member, and a pair of second terminals connected to the second photoelectric member, the pair of second terminals being opposite the first terminals.

The first photoelectric members may form at least one first series. Each of the at least one first series may include a plurality of first photoelectric members connected in series. The second photoelectric member may form at least one second series. Each of the at least one second series may include a plurality of second photoelectric members connected in series.

The unit portions may be arranged in one of a m×n matrix and a n×m matrix, where m is the number of the first photoelectric members in each of the at least one first series, and n is the number of the second photoelectric members in each of the at least one second series.

The first photoelectric members in the at least one first series and the second photoelectric members in the at least one second series may be arranged in different directions of a row direction and a column direction.

The solar cell may further include a circuit board mounted to the unit portions, and a plurality of conductive lines are on the circuit board. The plurality of conductive lines may contact lowermost photoelectric members of the unit portions.

Each of the unit portions may include a pair of ball grids connected to the lowermost photoelectric members, and the ball grids may contact the conductive lines.

The circuit board may be transparent.

### BRIEF DESCRIPTION OF THE DRAWINGS

Example embodiments of inventive concepts will be more clearly understood from the following brief description taken in conjunction with the accompanying drawings, in which:

FIG. 1 is a schematic sectional view of a unit portion of a solar cell according to example embodiments.

FIGS. 2 and 3 are graphs showing photo current density generated by a solar cell according to example embodiments as function of wavelength of solar light.

FIG. 4 is a sectional view of a solar cell according to example embodiments.

FIG. 5 shows an example of a solar cell shown in FIG. 4.

FIG. 6 illustrates an operation of the solar cell shown in FIG. 5.

FIG. 7 is a schematic sectional view of a solar cell according to example embodiments.

FIGS. 8 and 9 are schematic plan views of solar cells according to example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of like reference numbers in the various drawings is intended to indicate the presence of like elements or features throughout the different views.

### DETAILED DESCRIPTION

Example embodiments will be described more fully hereinafter with reference to the accompanying drawings. As those skilled in the art would realize, the described example embodiments may be modified in various different ways, all without departing from the spirit or scope. Example embodiments should not be construed as being limited to the embodiments set forth herein; rather, these example embodiments are provided so that this disclosure will be thorough and complete, and will fully convey concepts of example embodiments to those of ordinary skill in the art. In the drawing, parts having no relationship with the explanation are omitted for clarity, and like reference numerals designate the like elements throughout the specification so duplicative descriptions of like elements will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

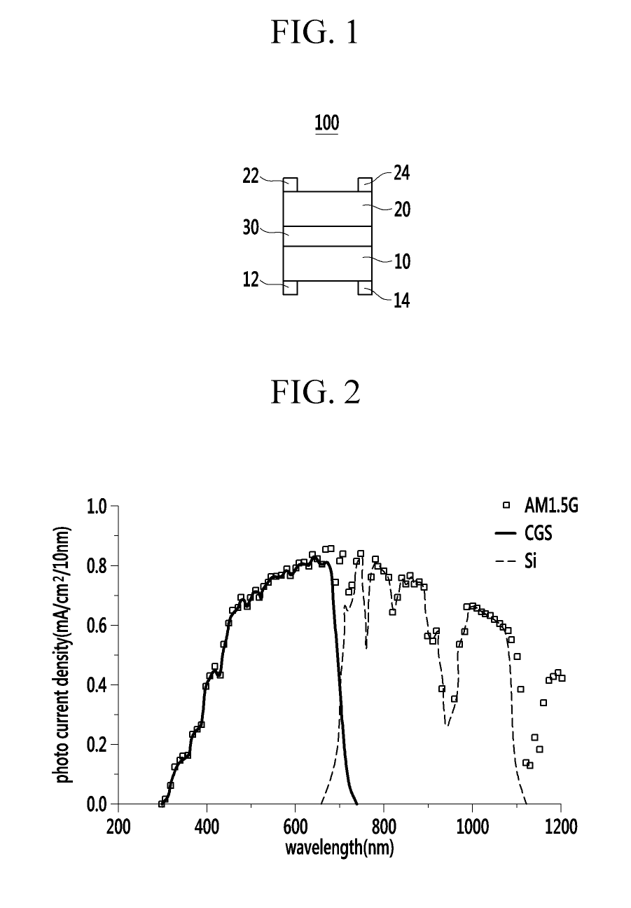

Referring to FIGS. 1 to 3, a unit portion of a solar cell according to example embodiments is described.

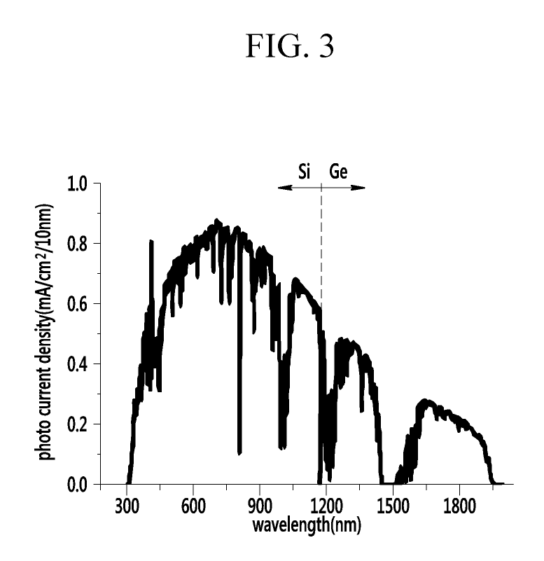

FIG. 1 is a schematic sectional view of a unit portion of a solar cell according to example embodiments, and FIGS. 2 and 3 are graphs showing photo current density generated by a solar cell according to example embodiments as a function of the wavelength of solar light.

A unit portion 100 of a solar cell may include a lower photoelectric member 10 and an upper photoelectric member 20. The unit portion 100 may further include an insulating layer 30 interposed between the photoelectric members 10 and 20. The insulating layer 30 may electrically separate the lower photoelectric member 10 and the upper photoelectric member 20, and may include a transparent insulating material such as SiO₂, but example embodiments are not limited thereto. For example, the insulating layer 30 alternatively may include silicon nitride or a transparent insulating polymer, and the like, but example embodiments are not limited thereto.

The lower and upper photoelectric members 10 and 20 include photoelectric material that can generate electricity upon receipt of light, and materials for the lower photoelectric member 10 and for the upper photoelectric member 20 may have different energy bandgap. For example, the bandgap of the upper photoelectric member 20 may be greater than that of the lower photoelectric member 10, and the difference in the bandgap between the lower photoelectric member 10 and the upper photoelectric member 20 may be about 0.3 to about 0.8 eV. If the bandgap difference between the photoelectric members 10 and 20 is lower than 0.3 eV or greater than 0.8 eV, an available wavelength range of light may decrease or an output voltage may be less than optimal, thereby reducing the efficiency of power generation. The bandgap of the lower photoelectric member 10 may be about 0.5 eV to about 1.5 eV, while the bandgap of the upper photoelectric member 20 may be about 1.1 eV to about 2.3 eV.

Examples of photoelectric materials for the photoelectric members 10 and 20 include various polymers and semiconductors such as Si, Ge, Cu—In—Ga—Se (CIGS), CdTe, and GaAs, but example embodiments are not limited thereto. Polycrystalline or single-crystalline silicon may have a bandgap of about 1.1 eV to about 1.2 eV, while amorphous silicon may have a higher bandgap of about 1.6 eV to about 1.7 eV. Germanium may have a bandgap of about 0.6 eV to about 0.7 eV, and CdTe and GaAs may have a bandgap of about 1.4 eV to about 1.5 eV. CIGS may have a bandgap of about 1.0 to about 1.7 eV depending on the composition ratio of In and Ga. A CIGS that contains mainly In but substantially no Ga, i.e., that contains Cu—In—Se as main ingredients (hereinafter referred to as “CIS”) may have a bandgap of about 1.1 eV. On the contrary, a CIGS that contains mainly Ga but substantially no In, i.e., that contains Cu—Ga—Se as main ingredients (hereinafter referred to as “CGS”) may have a bandgap about 1.7 eV. Polymers are known to have bandgaps of equal to or greater than about 1.7 eV.

The above-described materials are classified into three groups according to the degree of the bandgap. The first group has a bandgap of about 1.1 eV to about 1.2 eV and may include crystalline silicon and CIS (Cu—In—Se), and the second group has a bandgap equal to or greater than about 1.4 eV and may include amorphous silicon, CGS, CdTe, GaAs, and polymer. The last group has a bandgap equal to or lower than about 0.7 eV and may include Ge.

Among the three groups, the second group may be used mainly for the upper photoelectric member 20, while the last group mainly for the lower photoelectric member 10. The first group may be used for either the lower photoelectric member 10 or the upper photoelectric member 20 as the case may be. However, the usage is not limited thereto, and each of the groups may be used either the lower photoelectric member 10 or the upper photoelectric member 20 depending on the relative degree of the bandgap.

For example, when crystalline silicon and/or CIS in the first group is used for the upper photoelectric member 20, Ge in the last group may be used for the lower photoelectric member 10. On the contrary, when crystalline silicon and/or CIS in the first group is used for the lower photoelectric member 10, amorphous silicon, CGS, CdTe, GaAs, and polymer may be used for the upper photoelectric member 20. In this case, amorphous silicon and CGS that have bandgaps of about 1.6 eV to about 1.7 eV may give higher efficiency than CdTe and GaAs that have relatively low bandgaps in the second group.

The lower and upper photoelectric members 10 and 20 may be formed as substrates or thin films. The thin films may be formed by chemical deposition such as chemical vapor deposition (CVD) or by physical deposition such as sputtering, but example embodiments are not limited thereto.

Among the above-described materials, a crystalline semiconductor, for example a single crystalline silicon substrate, may be used for the lower photoelectric member 10. In this case, the insulating layer 30 may be deposited on the lower photoelectric member 10 by CVD, or a lamination process, etc., and a thin film of another photoelectric material such as CdTe or CIGS may be deposited on the insulating layer 30 to form the upper photoelectric member 20.

Each of the photoelectric members 10 and 20 may include a pair of terminals 12, 14, 22, and 24 that may include a low resistance metal such as Cu and/or Ag. In detail, a pair of lower terminals 12 and 14 are disposed under the lower photoelectric member 10, and a pair of upper terminals 22 and 24 are disposed on the upper photoelectric member 20. Therefore, the current flowing in each of the photoelectric members 10 and 20 flows outward through respective terminals 12 and 14 or 22 and 24. That is, the current in the lower photoelectric member 10 flows outward through the lower terminals 12 and 14, while that in the upper photoelectric member 20 through the upper terminals 22 and 24. However, since the lower photoelectric member 10 and the upper photoelectric member 20 are electrically isolated from each other, the current from the lower photoelectric member 10 may not pass through the upper terminals 22 and 24, and the current from the upper photoelectric member 20 may not pass through the lower terminals 12 and 14.

The positions of the terminals 12, 14, 22, and 24 may not be limited to those shown in FIG. 1, and the terminals 12, 14, 22, and 24 may be disposed at various positions. For example, at least one of the lower terminals 12 and 14 may be disposed on an upper surface of the lower photoelectric member 10 and in this case, there may be a margin for exposing a portion of the upper surface of the lower photoelectric member 10.

When the upper photoelectric member 20 includes a material having a relatively high energy bandgap and the lower photoelectric member 10 includes a material having a relatively low bandgap, light having a relatively short wavelength among solar light may be absorbed into the upper photoelectric member 20 to generate a current with a high voltage, while light having a relatively long wavelength may be absorbed into the lower photoelectric member 10 to generate a current with a relatively low voltage.

Referring to FIG. 2, when the upper photoelectric member 20 includes CGS and the lower photoelectric member 10 includes single crystalline silicon, the upper photoelectric member 20 may absorb light having a wavelength range lower than about 700 nm to generate a current with a relatively high voltage, and the lower photoelectric member 10 may absorb light having a wavelength range of about 700 nm to about 1,100 nm to generate a current with a relatively low voltage.

Referring to FIG. 3, when the upper photoelectric member 20 includes single crystalline silicon and the lower photoelectric member 10 includes Ge, the upper photoelectric member 20 may absorb light having a wavelength range lower than about 1,100 nm to generate a current with a relatively high voltage, and the lower photoelectric member 10 may absorb light having a wavelength range of about 1,100 nm to about 1,800 nm to generate a current with a relatively low voltage.

In the above-described solar cell structure, the magnitude of the current generated by the lower photoelectric member 10 may be different from the magnitude of the current generated by the upper photoelectric member 20. In this case, if the upper photoelectric member 20 and the lower photoelectric member 10 are electrically connected to each other, a net current of the solar cell may be determined by a lower one of the currents generated by the upper photoelectric member 20 and the lower photoelectric member 10. Therefore, an excess amount of the current generated by one of the photoelectric members 10 and 20 may not be utilized, which may reduce the efficiency of the solar cell. However, solar cells according to example embodiments electrically separate the upper photoelectric member 20 and the lower photoelectric member 10 to collect the currents having different magnitudes generated by the upper photoelectric member 20 and the lower photoelectric member 10 to be used without current loss, thereby increasing the efficiency.

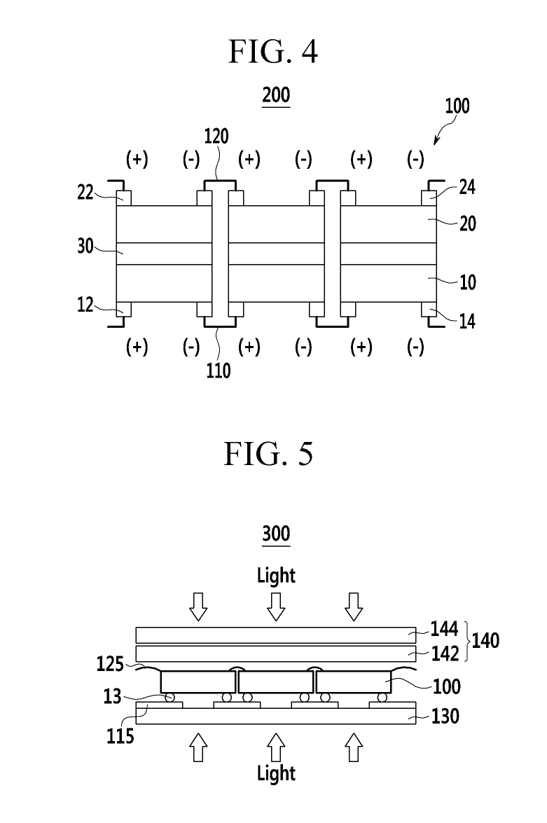

Next, various solar cells according to example embodiments are described in detail with reference to FIGS. 4 to 6.

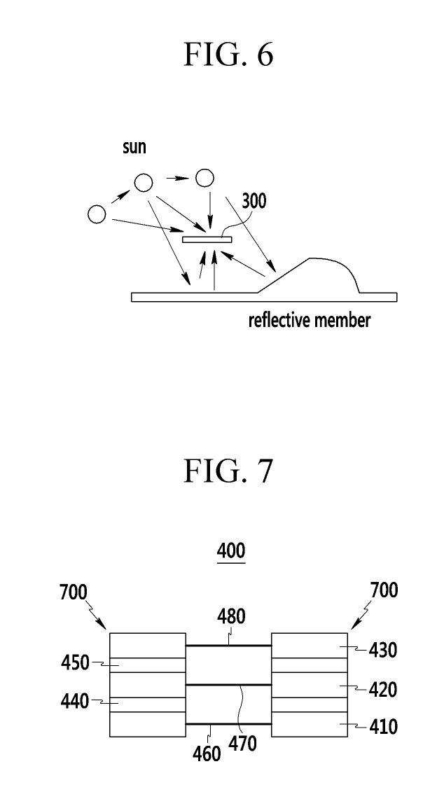

FIG. 4 is a sectional view of a solar cell according to example embodiments. FIG. 5 shows a detailed example of a solar cell shown in FIG. 4. FIG. 6 illustrates an operation of the solar cell shown in FIG. 5.

Referring to FIG. 4, a solar cell 200 according to example embodiments may include a plurality of unit portions 100 connected one another, and each unit portion 100 may have a structure shown in FIG. 1.

Each of the unit portions 100 may include lower and upper photoelectric members 10 and 20, and an insulating layer 30 disposed between the photoelectric members 10 and 20, and may further include a plurality of terminals 12, 14, 22 and 24. Adjacent unit portions 100 may be connected to each other by conductive connection members 110 and 120. The lower photoelectric members 10 may be connected to each other by lower connection members 110, and upper photoelectric members 20 may be connected to each other by upper connection members 120. Positive terminals 12 and 22 and negative terminals 14 and 24 of the photoelectric members 10 and 20 may be arranged alternately, and each of the connection members 110 and 120 may connect a positive terminal 12 or 22 of a photoelectric member 10 or 20 to a negative terminal 14 or 24 of an adjacent photoelectric members 10 or 20 to make current flow.

Referring to FIG. 5 that shows a detailed example of the solar cell 200 shown in FIG. 4. FIG. 5 shows unit portions 100 of a solar cell 300 may be mounted on a circuit board 130.

A plurality of conductive lines 115 may be printed on the circuit board 130, and a plurality of ball grids 13 may be disposed under the unit portions 100. The conductive lines 115 correspond to the lower connection members 110 shown in FIG. 4, and the ball grids 13 correspond to the lower terminals 12 and 14 shown in FIG. 4. The ball grids 13 may include conductive epoxy resin, but example embodiments are not limited thereto. Each of the conductive lines 115 may contact the ball grids 13 of two adjacent unit portions 100 such that the adjacent unit portions 100 may be electrically connected to each other.

Upper terminals (not shown) of adjacent unit portions 100 may be connected to each other by wire bonding using conductive wires 125, but example embodiments are not limited thereto. The lower terminals may be connected to each other by wire bonding instead of the circuit board 130 and the ball grids 13.

A transparent protective member 140 protecting the unit portions 100 may be disposed on the unit portions 100. The protective member 140 may have a dual-layered structure including a lower layer 142 and an upper layer 144. The lower layer 142 may include ethylene-vinyl acetate (EVA), and the upper layer 144 may include glass, but example embodiments are not limited thereto.

The circuit board 130 may include a transparent material such as glass or a transparent polymer, through which solar light or reflected solar light can pass, but example embodiments are not limited thereto. As shown in FIG. 6, light reflected by reflective members such as buildings, objects, earth ground, and reflective mirrors that are disposed near the solar cell 300 can pass through the transparent circuit board 130 to reach the unit portions 100, thereby enhancing power generation.

Now, a solar cell according to example embodiments is described in detail with reference to FIG. 7

FIG. 7 is a schematic sectional view of a solar cell according to example embodiments.

Referring to FIG. 7, a solar cell 400 according to example embodiments includes a plurality of unit portions 700.

Each of the unit portions 700 may include lower, middle, and upper photoelectric members 410, 420 and 430, and insulating layers 440 and 450 may be disposed between adjacent photoelectric members 410, 420, and 430. The energy bandgaps of the photoelectric members 410, 420, and 430 may be different from one another, and for example, the energy bandgap may increase from the lower photoelectric member 410 to the upper photoelectric members 430 via the middle photoelectric member 420. For example, the first group having an intermediate bandgap among the above-described three groups may used for the middle photoelectric member 420, the second group having a high bandgap for the upper photoelectric member 430, and the third group having a low bandgap for the lower photoelectric member 410.

In this way, the photoelectric members at different levels (or heights or floors) may generate currents with different magnitudes, and the photoelectric members 410, 420 or 430 at each level may be connected to each other to collect the currents having the same magnitude respectively. That is, the upper photoelectric members 430 may be connected to each other through upper connection members 480, the lower photoelectric members 410 through lower connection members 460, and the middle photoelectric members 420 through middle connection members 470. The upper and lower connection members 460 and 480 may be conductive lines on a circuit board or wires for wire bonding, and the middle connection members 470 may be wires for wire bonding.

Although stacked structures, each including two or three photoelectric members are described above, four or more photoelectric members having different energy bandgaps can be stacked with interposing insulating layers. In this case, the energy bandgap may increase from the bottom to the top, and photoelectric members at each level may be connected to each other since photoelectric members at different levels may generate currents with different magnitudes.

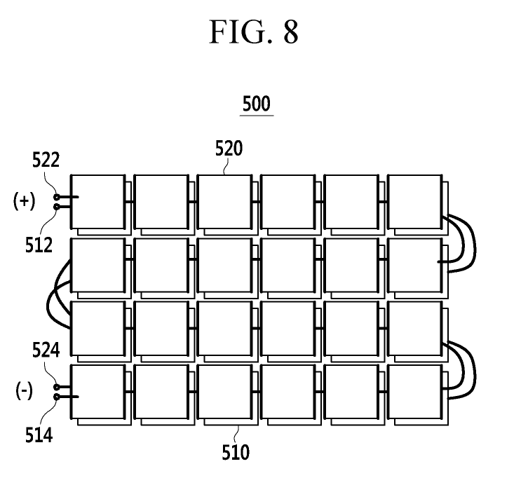

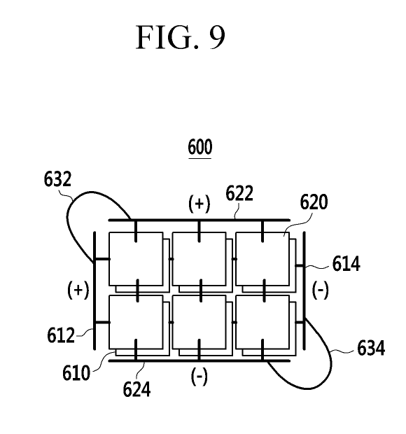

Now, examples of connection between unit portions in a solar cell are described with reference to FIGS. 8 and 9.

FIGS. 8 and 9 are schematic plan views of solar cells according to example embodiments.

Each of solar cells 500 and 600 shown in FIGS. 8 and 9 may include a plurality of unit portions arranged in a matrix.

The solar cell 500 shown in FIG. 8 includes upper photoelectric members 520 at an upper level and lower photoelectric members 510 at a lower level. The upper photoelectric members 520 in each row may be connected in series, and adjacent rows may be connected to each other at a left end or a right end. Therefore, the upper photoelectric members 520 as a whole may be connected in series. Likewise, the lower photoelectric members 510 as a whole may be connected in series.

However, a voltage generated by one of the lower photoelectric members 510 may be different from a voltage generated by one of the upper photoelectric members 520. If the number of the lower photoelectric members 510 in a series of the lower photoelectric members 510 (referred to as “lower series” hereinafter) is the same as the number of the upper photoelectric members 520 in a series of the upper photoelectric members 520 (referred to as “upper series” hereinafter), the terminal voltage of the lower series may be different from the terminal voltage of the upper series. Therefore, the solar cell 500 may have four terminals 512, 514, 522 and 524. In general, a photoelectric member having high bandgap may generate a voltage higher than a voltage generated by a photoelectric member having low bandgap.

Unlike the solar cell 500 shown in FIG. 8, the upper photoelectric members and lower photoelectric members may be connected in series in different directions. For example, the upper photoelectric members may be connected in series in a row direction, while the lower photoelectric members may be connected in series in a column direction, and vice versa. Furthermore, the number of series in each level may be two or more, and the plurality of series in each level may be connected in parallel to each other. That is, the plurality of upper series may be connected in parallel, and the plurality of lower series may also be connected in parallel. The number of the upper photoelectric members in an upper series may be different from the number of the lower photoelectric members in a lower series. In this case, the numbers of the photoelectric members in a series may be adjusted so that the terminal voltage of the upper series may be substantially the same as the terminal voltage of the lower series. In this case, the upper series and the lower series can be connected in parallel and thus the current generated by the upper photoelectric members and the current generated by the lower photoelectric members may be collected together to be outputted, which will be described with reference to FIG. 9.

A solar cell 600 shown in FIG. 9 may include unit portions that are arranged in a 2×3 matrix. The upper photoelectric members 620 are connected in a column direction, while the lower photoelectric members 610 connected in a row direction.

For example, it is assumed that a maximum voltage generated by an upper photoelectric member 620 is about 0.9 V and a maximum voltage generated by a lower photoelectric member 610 is about 0.6 V. Then, a voltage between terminals 622 and 624 of an upper series in each column is about 1.8 V (=0.9 V×2), and a voltage between terminals 612 and 614 of a lower series is also about 1.8 V (=0.6 V×2). Since the terminal voltage of the upper series is substantially the same as the terminal voltage of the lower series, the terminals of the upper series can be connected to corresponding terminals of the lower series as denoted by reference numerals 632 and 634.

In other words, it can be said that a lower solar cell of about 1.8 V obtained by connecting three lower photoelectric members 610 in series and an upper solar cell of about 1.8 V obtained by connecting two upper photoelectric members 620 in series is connected in parallel. As a result, small currents generated by the lower photoelectric members 610 may not limit large currents generated by the upper photoelectric members 620, but may be added to the large currents to form a greater current. Further, while FIG. 9 illustrates a single solar cell 600, example embodiments are not limited thereto. A plurality of solar cells 600 may be connected together in series, parallel, and/or series-parallel to form a solar system for achieving the desired voltage, current, and/or power generation output.

As described above, since an upper photoelectric member 620 and a lower photoelectric member 610 form a unit portion, a solar cell includes the same numbers of the upper photoelectric members 620 and the lower photoelectric members 610. Therefore, an appropriate arrangement under this condition of the solar cells may be considered.

For example, when three upper series are connected in a row direction, and two lower series are connected in a column direction, both the number of the upper photoelectric members 620 and the number of the lower photoelectric members 610 are six, respectively, and thus above-described condition can be satisfied.

When generalizing the structure shown in FIG. 9, the terminal voltage of the upper/lower series may be a common multiple of the voltage generated by the upper photoelectric members 620 and the voltage generated by the lower photoelectric members 610. If one upper series and one lower series are used, the number of the upper photoelectric members 620 and the number of the lower photoelectric members 610 are different from each other and therefore, and it may not be applied to example embodiments where one upper photoelectric member 620 and one lower photoelectric member 610 form one unit portion. Hence, two or more of either or both of the upper series and the lower series may be connected in parallel so that the number of the upper photoelectric members 620 may be the same as the number of the lower photoelectric members 610. In order to satisfy this condition, the unit portions 100 may be arranged in a matrix, where the number of rows is the same as the number of the upper photoelectric members 620 in one upper series and the number of columns is the same as the number of the lower photoelectric members 610 in one lower series. The columns and the rows may be interchanged.

For example, it is assumed that a voltage generated by a lower photoelectric member 610 is V1, and a voltage generated by an upper photoelectric member 620 is V2. When V1×m=V2×n where m and n are natural numbers, the unit portions 100 may be arranged in a m×n or n×m matrix. In case of m×n matrix, the lower photoelectric members 610 may be connected in series in a column direction, the upper photoelectric members 620 may be connected in series in a row direction. In addition, n lower series may be connected in parallel, and m upper series may also be connected in parallel. Finally, the parallel-connected lower series and the parallel-connected upper series may be connected in parallel again. In case of n×m matrix, the directions of the connections of the upper photoelectric members 620 and the lower photoelectric members 610 may be interchanged. The output voltage V of the solar cell power generation in this structure may be obtained by V=V1×m=V2×n.

Instead of manufacturing and connecting a large number of the unit portions 100 at the same time, an appropriate number of unit modules, each including an appropriate number of the unit portions 100, may be manufactured and then connected to each other. In this case, a terminal voltage of a unit module may be a least common multiple of a voltage generated by a lower photoelectric member 610 and a voltage of an upper photoelectric member 620. That is, m and n may be determined so that (a least common multiple of V1 and V2)=V1×m=V2×n in the above example. A unit module may have a structure shown in FIG. 5.

In each module, the series disposed in different levels may be connected in parallel such that each module has a pair of output terminals. Otherwise, each module may have a plurality of pairs of output terminals, each pair assigned to each level. In the latter case, the output terminals of adjacent modules may be connected level to level, and the series in different levels of a first or last module may be connected to each other so that a solar cell can have only a pair of output terminals.

As described above, photoelectric members having different energy bandgaps may be stacked to form a unit portion, and photoelectric members at different levels may be electrically separated. A plurality of the unit portions are arranged such that the photoelectric members at each level may be connected in series or in parallel and the photoelectric members at different levels may be connected in parallel. In this way, the currents with different magnitudes generated by the photoelectric members at different levels may be collected to increase the efficiency of power generation.

While some example embodiments have been particularly shown and described, it will be understood by one of ordinary skill in the art that variations in form and detail may be made therein without departing from the spirit and scope of the claims.

What is claimed is:

1. A solar cell comprising:
a plurality of unit portions,
each of the unit portions including a stacked structure comprising a plurality of photoelectric members at a plurality of levels and at least one insulating layer between the photoelectric members,
the photoelectric members at different levels having different energy bandgaps, and
the photoelectric members at the same levels being connected to each other.

2. The solar cell of claim 1, wherein
the photoelectric members at the same levels are configured to generate currents with the same magnitude, and
the photoelectric members at different levels are configured to generate currents with different magnitudes.

3. The solar cell of claim 2, wherein
the photoelectric members at the same levels are configured to generate voltages with the same magnitude, and
the photoelectric members at different levels are configured to generate voltages with different magnitudes.

4. The solar cell of claim 3, wherein
the photoelectric members in each level form at least one series, and
the photoelectric members in each of the at least one series are connected in series.

5. The solar cell of claim 4, wherein
the series in different levels are configured to generate substantially the same terminal voltages and
the series in different levels are connected in parallel to each other.

6. The solar cell of claim 5, wherein each of the unit portions includes a double-layered structure, and
the plurality of photoelectric members in each unit portion comprises:
a first photoelectric member; and
a second photoelectric member electrically separated from the first photoelectric member,
wherein the first photoelectric member and the second photoelectric member are in different levels.

7. The solar cell of claim 6, wherein each of the unit portions further comprise:
a pair of first terminals connected to the first photoelectric member; and
a pair of second terminals connected to the second photoelectric member, the pair of second terminals being opposite the first terminals.

8. The solar cell of claim 6, wherein
the first photoelectric members form at least one first series,
each of the at least one first series including a plurality of first photoelectric members connected in series; and
the second photoelectric member form at least one second series,
each of the at least one second series includes a plurality of second photoelectric members connected in series.

9. The solar cell of claim 8, wherein
the unit portions are arranged in one of a m×n matrix and a n×m matrix, wherein
m is the number of the first photoelectric members in each of the at least one first series, and
n is the number of the second photoelectric members in each of the at least one second series.

10. The solar cell of claim 9, wherein
the first photoelectric members in the at least one first series and the second photoelectric members in the at least one second series are arranged in different directions of a row direction and a column direction.

11. The solar cell of claim 1, further comprising:
a circuit board mounted to the unit portions,
a plurality of conductive lines are on the circuit board,
the plurality of conductive lines contacting lowermost photoelectric members of the unit portions.

12. The solar cell of claim 11, wherein
each of the unit portions comprises a pair of ball grids connected to the lowermost photoelectric members, and
the ball grids contact the conductive lines.

13. The solar cell of claim 11, wherein
the circuit board is transparent.
